(19) United States
(12) Patent Application Publication
(10) Pub. No.: US 2025/0384912 A1
(43) Pub. Date: Dec. 18, 2025

(54) SEMICONDUCTOR MEMORY DEVICE AND CONTROL METHOD THEREOF

(71) Applicant: Winbond Electronics Corp., Taichung City (TW)

(72) Inventor: Takuya KADOWAKI, Yokohama (JP)

(73) Assignee: Winbond Electronics Corp., Taichung City (TW)

(21) Appl. No.: 19/058,148

(22) Filed: Feb. 20, 2025

(30) Foreign Application Priority Data
Jun. 12, 2024 (JP) 2024-095027

(51) Int. Cl. G11C 11/406; G11C 11/4091

(52) U.S. Cl. CPC G11C 11/40603; G11C 11/40622; G11C 11/4091

(57) ABSTRACT

The present invention provides a semiconductor memory device and a control method thereof. The sensing margin of the sense amplifier can be improved even when a sequence of offset cancellation operations is being performed on the plurality of sense amplifiers of each of the plurality of pages. The semiconductor memory device includes a control section configured to perform at least one specific operation of a sequence of offset cancellation operations on the plurality of sense amplifiers of the each of the plurality of pages. The specific operation serves to provide a power supply voltage common to the each of the plurality of pages to the plurality of sense amplifiers. The control section controls a timing point of the sequence of offset cancellation operations of each of the plurality of pages while the sequence of offset cancellation operations is being performed on the each of the plurality of pages.

### CROSS REFERENCE TO RELATED APPLICATIONS

This application claims priority of Japan Patent Application No. 2024-095027, filed on Jun. 12, 2024, the entirety of which is incorporated by reference herein.

### BACKGROUND OF THE INVENTION

### Field of the Invention

The present invention relates to semiconductor memory devices and control methods thereof.

### Description of the Related Art

A semiconductor memory device, such as a dynamic random access memory (DRAM), reads data by generating a weak potential difference across a pair of bit lines from data stored in a memory cell and amplifying this potential difference with a sense amplifier. A pair of N-channel type field effect transistors (Metal-Oxide-Semiconductor Field Effect Transistor (nMOSFET)) and a pair of P-channel type field effect transistors (pMOSFET) are provided in the sense amplifier. However, the difference in performance of these transistors (which is also called the characteristic difference) generates an offset voltage that reduces the sensing margin. Therefore, a semiconductor memory device has been developed that can eliminate the offset voltage (e.g., Patent Document 1: U.S. Pat. No. 9,202,531).

### BRIEF SUMMARY OF THE INVENTION

In the technique documented in Patent Document 1, an offset cancellation operation, a charge sharing operation that activates a word line to generate a sense signal voltage on a bit line, a pre-sensing operation that amplifies the sense signal voltage and a bit line charging operation (referred to as a restore operation in Patent Document 1) for transmitting sensing data to a pair of bit lines are performed in a sequence of offset cancellation operations in order to cancel the offset voltage of a sense amplifier.

In addition, the sequence of offset cancellation operations may be performed on a page unit comprising a plurality of memory cells. FIG. 1(A) shows an example of changes in the power supply voltage VBLH and the ground voltage VSS when performing the sequence of offset cancellation operations on a single page (page 1 is shown as an example). Between time t1 and time t2, the offset cancellation operation (OC) is performed on a plurality of sense amplifiers connected to each of the memory cells in Page 1. Between time t2 and time t3, the charge sharing operation (CS) is performed on the sense amplifiers. Furthermore, the pre-sensing operation (PS) is performed on the sense amplifiers between time t3 and time t4, and the bit line charging operation (BC) is performed on the sense amplifiers at time t4. In this case, when performing the offset cancellation operation (OC), the pre-sensing operation (PS) and the bit line charging operation (BC) in the sequence of offset cancellation operations, each sense amplifier is connected to the power supply voltage VBLH and the ground voltage VSS. Due to the current consumption of each sense amplifier, the power supply noise is generated on the power supply voltage VBLH and the ground voltage VSS.

However, DRAM needs to be periodically charged by a memory retention operation (refresh), and such refresh can usually be performed on the page units. In this case, as shown in FIG. 1(B), when performing the sequence of offset cancellation operations (offset cancellation operation, pre-sensing operation and bit line charging operation) simultaneously on the pages (from page 1 to page 4 shown as an example), the power supply noise generated at the common power supply voltage VBLH and the ground voltage VSS of each page increases. Therefore, during operations such as refreshing, when performing the sequence of offset cancellation operations on the pages, the sense margin of the sense amplifier may be reduced due to the influence of power supply noise.

In view of the above problems, the present invention provides a semiconductor memory device and a control method thereof, which can improve the sense margin of the sense amplifier even when performing the sequence of offset cancellation operations on the sense amplifiers of each page.

In order to solve the above problems, the present invention provides a semiconductor memory device. The semiconductor memory device comprises a plurality of pages and a control section. Each of the plurality of pages comprises a plurality of memory cells and a plurality of sense amplifiers. The plurality of memory cells are connected to the same word line. The plurality of sense amplifiers are connected to the plurality of memory cells. The control section is configured to perform at least one specific operation of a sequence of offset cancellation operations on the plurality of sense amplifiers of the each of the plurality of pages, the specific operation serves to provide a power supply voltage to the plurality of sense amplifiers, and the power supply voltage is common to the each of the plurality of pages. The control section controls a timing point of the sequence of offset cancellation operations of each of the plurality of pages when while the sequence of offset cancellation operations is being performed on the each of the plurality of pages, wherein the specific operation is not performed on other pages other than the any one of the plurality of pages while the specific operation is performed on any one of the plurality of pages.

According to the present invention, since the specific operation of providing a common power supply voltage to the sense amplifier is carried out on only one page at a time, while the specific operation is not performed on other pages, it is possible to avoid providing the power supply voltage to the sense amplifiers of all pages simultaneously. Therefore, for example, the power noise generated at the power supply voltage can be reduced compared to when each sense amplifier is connected to the power supply voltage. Thus, the sense margin of the sense amplifier can be improved even when the sequence of offset cancellation operations is performed on the sense amplifiers of each of the pages.

In addition, the present invention provides a control method of the semiconductor memory device, wherein the semiconductor memory device comprises a plurality of pages, a plurality of sense amplifiers, and a control section. Each of the plurality of pages comprises a plurality of memory cells connected to the same word line. The plurality of sense amplifiers are connected to each of the plurality of memory cells. The control section performs at least one specific operation of a sequence of offset cancellation operations on the plurality of sense amplifiers of the each of the plurality of pages, the specific operation serves to provide a power supply voltage to the plurality of sense amplifiers. The power supply voltage is common to the each of the plurality of pages. The control method comprises: controlling, by the control section, a timing point of for performing the sequence of offset cancellation operations on the each of the plurality of pages while the sequence of offset cancellation operations is being performed on the each of the plurality of pages, wherein the control method is executed as follows: not performing the specific operation on other pages other than the any one of the plurality of pages during a period of time when the specific operation is performed on any one of the plurality of pages.

According to the semiconductor memory device of the present invention and the control method thereof, it is possible to improve the sense margin of the sense amplifier even when the sequence of offset cancellation operations is performed on the sense amplifiers of each of the pages.

### BRIEF DESCRIPTION OF THE DRAWINGS

FIG. 1(A) is an example diagram of the variations of the power supply voltage and ground voltage when the sequence of offset cancellation operations is performed on a page in the prior art.

FIG. 1(B) is an example diagram of the variations of the power supply voltage and ground voltage when the sequence of offset cancellation operations is performed simultaneously on the pages in the prior art.

FIG. 2 is an example diagram of the semiconductor memory device configuration in an embodiment of the present invention.

FIG. 3 is an example diagram of the sense amplifier configuration.

FIG. 4 is an example diagram of the control section configuration.

FIG. 5 is an example timing diagram of the sense amplifier operation during the sequence of offset cancellation operations.

FIG. 6 is an example diagram of the variations of the power supply voltage and ground voltage when the sequence of offset cancellation operations is performed on the pages in an embodiment of the present invention.

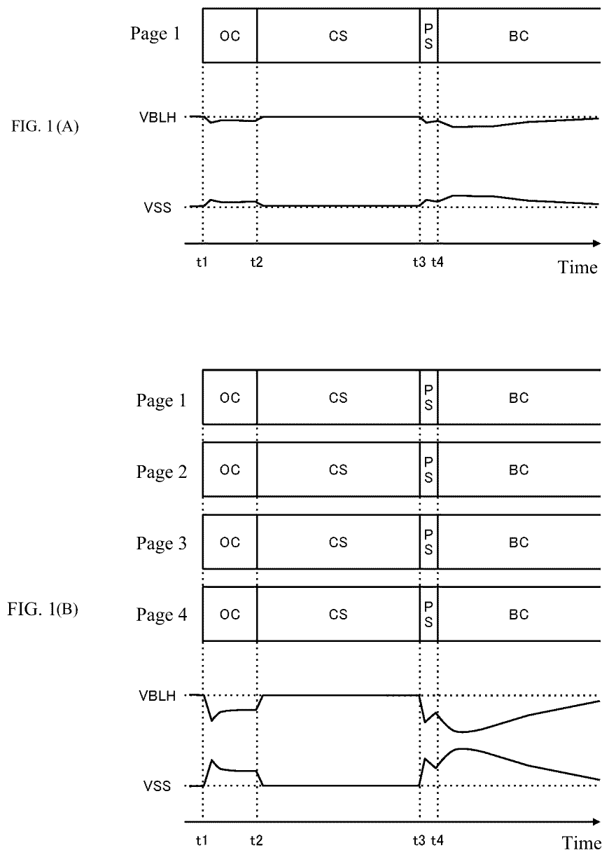

### DETAILED DESCRIPTION OF THE INVENTION

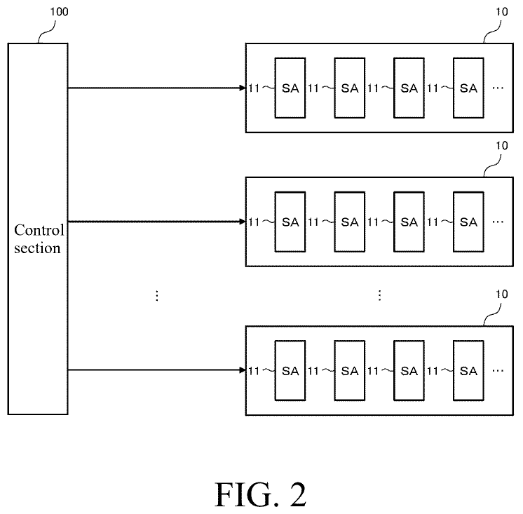

As shown in FIG. 2, a semiconductor memory device comprises a plurality of pages 10 and a control section 100. Furthermore, each page 10 comprises a plurality of memory cells (omitted in the figure) connected to the same word line and a plurality of sense amplifiers (SA) 11 connected to the memory cells.

In this embodiment, the control section 100 is configured to perform an offset cancellation operation on the sense amplifiers 11 of each of the pages 10, which includes at least one specific operation. The specific operation provides the sense amplifiers 11 with a power supply voltage VBLH that is common to each page 10. In addition, the control section 100 is configured to perform the sequence of offset cancellation operations on each of the pages 10 to control the timing point for performing the sequence of offset cancellation operations on each of the pages 10. Control is performed in such a manner that when the specific operation is being performed on any one page 10, the specific operation is not performed on any of the other pages.

The specific operation may comprise one or more of the following: an offset cancellation operation (OC), a pre-sensing operation (PS), and a bit line charging operation (BC) of the sense amplifiers 11. Thereby, control may be performed in the following manner: during a period in which any one of the plurality of pages 10 performs any one of the offset cancellation operation (OC), the pre-sensing operation (PS), or the bit line charging operation (BC) on the plurality of sense amplifiers 11, then other pages 10 do not perform any one of the offset cancellation operation (OC), the pre-sensing operation (PS) and the bit line charging operation (BC) of the plurality of sense amplifiers 11.

In addition, the sequence of offset cancellation operations may include an offset cancellation operation (OC), a charge sharing operation (CS) of the sense amplifiers 11 after the offset cancellation operation, a pre-sensing operation (PS) after the charge sharing operation (CS), and a bit line charging operation (BC) after the pre-sensing operation (PS). As a result, the offset voltage of the sense amplifiers 11 can be reduced to increase the sense margin of the sense amplifiers 11.

In addition, the control section 100 may be configured to perform the sequence of offset cancellation operations on the sense amplifiers 11 of each of the pages 10 while the memory cells of each of the pages 10 are being refreshed. Accordingly, even if the sequence of offset cancellation operations is being performed on the pages 10 during the refresh, the sense margin of the sense amplifiers 11 can be improved.

Furthermore, the control section 100 may be configured to stop providing the power supply voltage VBLH to the sense amplifiers 11 of any page 10 if other pages 10 start performing the specific operation simultaneously. Thus, the power supply voltage VBLH to the sense amplifiers 11 of any pages 10 can be suppressed while the power supply voltage VBLH is being provided to the sense amplifiers 11 of other pages 10.

In addition, the control section 100 may be configured so that when the specific operation is performed on any one page 10, if other pages 10 begin to perform the specific operation, then the specific operation is not performed on other pages 10 until the specific operation is finished on any one page 10. Thus, it is possible to avoid providing the power supply voltage VBLH to the sense amplifiers 11 of other pages 10 while the power supply voltage VBLH is being provided to the sense amplifier 11 of any one page 10.

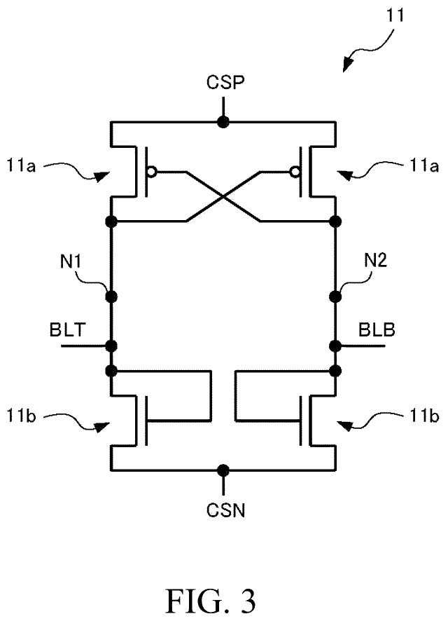

FIG. 3 illustrates an exemplary configuration of the sense amplifier 11. As shown in FIG. 3, the sense amplifier 11 includes a pair of pMOSFETs 11a connected to a node CSP on the high voltage power supply side and a pair of nMOSFETs 11b connected to a node CSN on the low voltage power supply side. In addition, the nodes connected between the pair of pMOSFETs 11a and the pair of nMOSFETs 11b are a pair of complementary bit lines BLT, BLB (hereinafter referred to as “a pair of bit lines BLT, BLB”). The pair of pMOSFETs 11a is an example of “a pair of first transistors” of the present invention and the pair of nMOSFETs 11b is an example of “a pair of second transistors” of the present invention.

Furthermore, in the embodiment, the sense amplifier 11 includes a loop for performing the sequence of offset cancellation operations as documented, for example, in Patent Document 1. It should be noted that in FIG. 3, a MOSFET used as a switch for enabling the sequence of offset cancellation operations is omitted for simplicity of illustration.

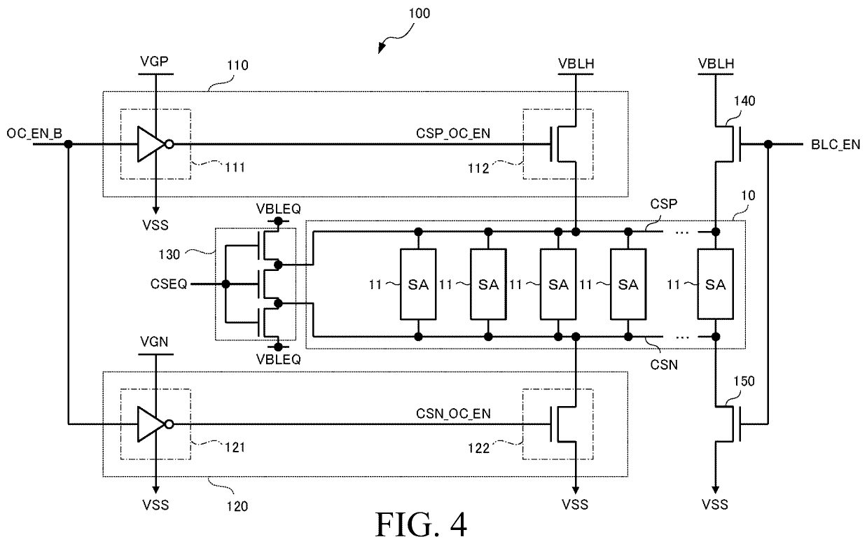

FIG. 4 illustrates a detailed example configuration of the control section 100. It should be noted that in the example in FIG. 4, only one page 10 is shown for simplicity of illustration. As shown in FIG. 4, the control section 100 includes a first control portion 110 and a second control portion 120. Furthermore, the first control portion 110 includes a high voltage power side control portion 111 and a high voltage power side driver 112. Furthermore, the second control portion 120 includes a low voltage power side control portion 121 and a low voltage power side driver 122.

The high voltage power supply side control portion 111 of the first control portion 110 includes a NOT circuit to which a voltage VGP is applied and a signal OC_EN_B is input. When the signal OC_EN_B input is low level, the high voltage power supply side control portion 111 outputs a signal CSP_OC_EN which is high level. The voltage of the high level signal CSP_OC_EN is equal to the voltage VGP. In addition, the high voltage power supply side driver 112 of the first control section 110 includes an nMOSFET. The nMOSFET includes a drain terminal connected to a power supply voltage VBLH, a source terminal connected to a node CSP of the page 10 and a gate terminal into which the signal CSP_OC_EN is input.

The low voltage power supply side control portion 121 of the second control portion 120 includes a NOT circuit to which a voltage VGN is applied and the signal OC_EN_B is input. When the signal OC_EN_B input is low level, the low voltage power supply side control portion 121 outputs a signal CSN_OC_EN which is high level. The voltage of the high level signal CSN_OC_EN is equal to the voltage VGN. In addition, the low voltage power supply side driver 122 of the second control portion 120 includes an Nmosfet. The nMOSFET includes a drain terminal connected to a node CSN of the page 10, a source terminal connected to a ground voltage VSS and a gate terminal into which the signal CSN_OC_EN is input.

In addition, the control section 100 includes a voltage providing section 130 that provides an equalizer voltage VBLEQ. In the example in FIG. 4, the voltage providing section 130 has three interconnected nMOSFETs, and each gate terminal of the nMOSFETs is input with a signal CSEQ. In the three nMOSFETs, the drain terminal of a first nMOSFET is connected to the equalizer voltage VBLEQ, and the source terminal of the first nMOSFET is connected to the drain terminal of a second nMOSFET. The source terminal of the second nMOSFET is connected to the drain terminal of a third nMOSFET, and the source terminal of the third nMOSFET is connected to the equalizer voltage VBLEQ. Furthermore, the node between the source terminal of the first nMOSFET and the drain terminal of the second nMOSFET is connected to the node CSP, and the node between the source terminal of the second nMOSFET and the drain terminal of the third nMOSFET is connected to the node CSN.

In addition, the control section 100 includes an nMOSFET 140. The nMOSFET 140 includes a drain terminal connected to the power supply voltage VBLH, a source terminal connected to the node CSP and a gate terminal into which a signal BLC_EN is input. Furthermore, the control section 100 includes an nMOSFET 150. The nMOSFET 150 includes a drain terminal connected the node CSN, a source terminal connected to the ground voltage VSS and a gate terminal into which the signal BLC_EN is input.

In the embodiment, the control section 100 may be configured so that when the charge sharing operation (CS) is being performed on any one page 10, the other voltage (equalizer voltage VBLEQ) may be supplied to the sense amplifiers 11 of any one page 10 in place of the power supply voltage VBLH. In addition, the other voltage (equalizer voltage VBLEQ) may be a voltage lower than the power supply voltage VBLH (e.g., a voltage half of the power supply voltage VBLH). Therefore, when the charge sharing operation (CS) is performed on any one page 10, since the other voltage (equalizer voltage VBLEQ) is supplied to the sense amplifier 11 of any one page 10, the power supply voltage VBLH to the sense amplifier 11 at any one page 10 can be stopped (or suppressed).

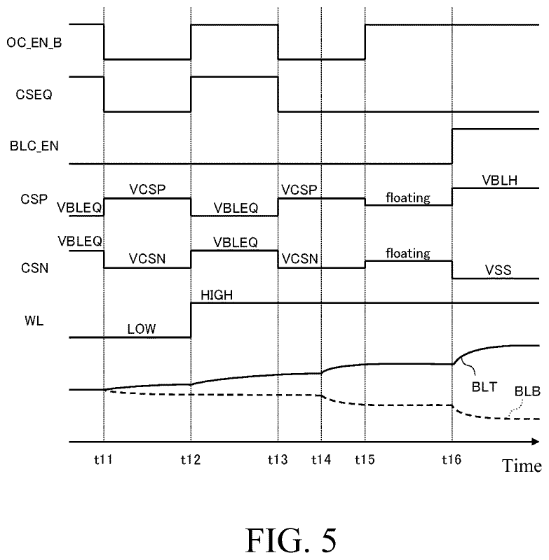

FIG. 5 illustrates an embodiment of the operation of the control section 100 when the sequence of offset cancellation operations is performed on any one page 10. In this embodiment, it is assumed that the offset cancellation operation (OC) is performed between time t11 and time t12, the charge sharing operation (CS) is performed between time t12 and time t13, the pre-sensing operation (PS) is performed between time t13 and time t14, the bit line charging operation (BC) is performed between time t14 and time t15, the bit line charge retention operation (BCP) is performed between time t15 and time t16, and the bit line charging operation (BC) is restarted after time t16. In addition, the respective operations of the offset cancellation operation (OC), the charge sharing operation (CS), the pre-sensing operation (PS), and the bit line charging operation (BC) may be the same as those described in the Patent Document 1 described above.

When the offset cancellation operation (OC) is started at time t11, the signal OC_EN_B and the signal CSEQ become low level. In addition, the signal BLC_EN is low level. Therefore, the signal CSP_OC_EN having a high level of voltage VGP is input to the high voltage power supply side driver 112 and the power supply voltage VBLH is connected to the node CSP, where the voltage VCSP supplied to the node CSP is a voltage that decreases from the power supply voltage VBLH due to the on-resistance of the nMOSFET of the high voltage power supply side driver 112. In addition, the signal CSN_OC_EN having a high level of the voltage VGN is input to the low voltage power supply side driver 122 and the ground voltage VSS is connected to the node CSN, where the voltage VCSN is supplied to the node CSN.

When the charge sharing operation (CS) is started at time t12, the signal OC_EN_B and the signal CSEQ become high level. In addition, the signal BLC_EN is low level. Therefore, the high voltage power supply side driver 112 is turned off and disconnects the power supply voltage VBLH from the node CSP, and the low voltage power supply side driver 122 is turned off and disconnects the ground voltage VSS from the node CSN. Furthermore, the equalizer voltage VBLEQ is provided to the node CSP and the node CSN from the voltage providing section 130. Thus, when the charge sharing operation is performed on any one page 10, other voltages (equalizer voltages VBLEQ) are provided to each sense amplifier 11 of any one of the pages 10. Furthermore, a voltage is applied to the word line (WL) of the access object at time t12.

When the pre-sensing operation (PS) is started at time t13, the signal OC_EN_B and the signal CSEQ become low level. In addition, the signal BLC_EN is low level. Therefore, the power supply voltage VBLH is connected to the node CSP and the ground voltage VSS is connected to the node CSN at the same time, time t11. Next, the voltage VCSP is supplied to the node CSP and the voltage VCSN is supplied to the node CSN.

At time t14, when the pair of bit lines BLT, BLB (isolated) is disconnected from the nodes (e.g., nodes N1, N2 in FIG. 3) of the sense amplifier 11, the bit line charging operation (BC) is started. Herein, the operation of disconnecting the pair of bit lines BLT, BLB from the nodes (nodes N1, N2) of the sense amplifier 11 may be the same as the operation described in the Patent Document 1 described above.

Then, when the specific operation (e.g., pre-sensing operation (PS)) is started on other pages 10 other than, for example, any one page 10, the bit line charge retention operation (BCP) is started at time t15. At this time, the signal OC_EN_B becomes high level, and the signal CSEQ and the signal BLC_EN are low level. In this case, the node CSP and the node CSN are in the floating state because neither the node CSP nor the node CSN is connected to any voltage.

Then, when the pre-sensing operation (PS) performed in all of the pages 10 is completed, the bit line charging operation (BC) is restarted at time t16. At this time, the signal OC_EN_B is high level and the signal CSEQ is low level. In addition, the signal BLC_EN becomes high level. As a result, the power supply voltage VBLH is supplied to the node CSP through the nMOSFET 140 and the ground voltage VSS is supplied to the node CSN through the nMOSFET 150. In this way, the sequence of offset cancellation operations is performed on any one of the pages 10.

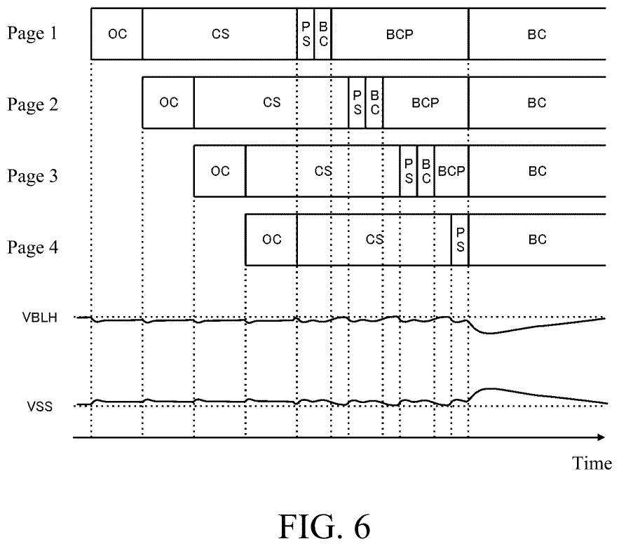

FIG. 6 illustrates an example of the changes in the power supply voltage and the ground voltage when the sequence of offset cancellation operations is performed on the pages 10. In the present invention, the control section 100 may be configured to perform the offset cancellation operation (OC) at the (i+1)-th page when the offset cancellation operation (OC) is completed at the i-th page (i is an integer greater than or equal to 1 and less than or equal to N) under the case where N pages are set up (N is an integer greater than or equal to 2), as shown in FIG. 6. Therefore, the timing point at which the sequence of offset cancellation operations is started on the pages 10 may be separated.

In addition, the control section 100 may be configured to perform the bit line charging operation (BC) on all of the pages 10 when the pre-sensing operation (PS) on all of the pages 10 is completed, as shown in FIG. 6. In this case, since the pre-sensing operation (PS) has already determined the contents of the sensing data of each sense amplifier 11 in the pages 10, the correct data may also be transmitted to the pair of bit lines BLT, BLB, even if the bit line charging operation (BC) is being performed on all of the pages 10 at the same time.

In an embodiment of FIG. 6, during the period of time when the specific operation (e.g., offset cancellation operation (OC), pre-sensing operation (PS) or bit line charging operation (BC)) is performed on any one of the pages 10, the control section 100 would not perform the specific operation (e.g., offset cancellation operation (OC), pre-sensing operation (PS) or bit line charging operation (BC)) on other pages 10 (e.g., page 2 to page 4) other than any one of the pages 10 (e.g., page 1), such that the control section 100 can control the timing point at which the sequence of offset cancellation operations is performed on each of the pages 10 (i.e., the control section 100 controls the logical level of the signals OC_EN_B, CSEQ and BLC_EN that are sent from each of the pages 10).

In addition, in the embodiment of FIG. 6, during the period of time when the specific operation (e.g., bit line charging operation (BC)) is performed on any one of the pages 10 (e.g., page 1), the control section 100 would stop providing the sense amplifier 11 with the power supply voltage VBLH (i.e., the operation of not providing the power supply voltage VBLH to the sense amplifier 11 is performed (herein, the bit line charge retention operation (BCP))) on any one of the pages 10 (e.g., page 1) if the specific operation is started on other pages 10 (e.g., page 2).

Alternatively, in the embodiment of FIG. 6, during the period of time when the specific operation (e.g., offset cancellation operation (OC)) is performed on any one of the pages 10 (e.g., page 1), if the specific operation (e.g., offset cancellation operation (OC)) is started on another page 10 (e.g., page 2), the control section 100 will not perform the specific operation (e.g., offset cancellation operation (OC)) on the other page 10 (e.g., page 2) until the specific operation (e.g., offset cancellation operation (OC)) is completed on the current page (e.g., page 1). Therefore, as shown in FIG. 6, the power noise generated in the power supply voltage VBLH and the ground voltage VSS can be reduced by suppressing the power supply voltage VBLH and the ground voltage VSS supplied simultaneously to each sense amplifier 11 of the pages 10.

As described above, the semiconductor memory device and the control method thereof according to the embodiment of the present invention, the specific operation of providing the power supply voltage VBLH that is common to each page to the sense amplifier 11 is performed on any one page 10, the specific operation is controlled not to be performed on other pages 10. Therefore, this can prevent the power supply voltage VBLH from being provided to each sense amplifier 11 of the pages 10 simultaneously. As a result, the power noise generated in the power supply voltage VBLH can be reduced (i.e., it is lower than when each sense amplifier 11 of the pages 10 is connected to the power supply voltage VBLH). Thus, the sense margin of the sense amplifier can be improved even while the sequence of offset cancellation operations is being performed on the sense amplifiers 11 in each of the pages 10.

In the above embodiment, the control section 100 includes a first control portion 110, a second control portion 120, a voltage providing section 130, an nMOSFET 140, an nMOSFET 150 and the like as an example, but the present invention is not limited thereto. For example, the control section 100 may include other circuits capable of generating the same function effect as the above embodiment.

What is claimed is:

1. A semiconductor memory device, comprising:
a plurality of pages, wherein each of the plurality of pages comprises:
a plurality of memory cells, connected to the same word line; and
a plurality of sense amplifiers, connected to the plurality of memory cells; and
a control section, configured to perform at least one specific operation of a sequence of offset cancellation operations on the plurality of sense amplifiers of the each of the plurality of pages, the specific operation serves to provide a power supply voltage to the plurality of sense amplifiers, and the power supply voltage is common to the each of the plurality of pages;
the control section controls a timing point of the sequence of offset cancellation operations of each of the plurality of pages while the sequence of offset cancellation operations is being performed on the each of the plurality of pages, wherein the specific operation is not performed on other pages other than the any one of the plurality of pages when the specific operation is performed on any one of the plurality of pages.

2. The semiconductor memory device as claimed in claim 1, wherein the control section is configured to perform the sequence of offset cancellation operations on the plurality of sense amplifiers of each of the plurality of pages when the plurality of memory cells of each of the plurality of pages is refreshed.

3. The semiconductor memory device as claimed in claim 1, wherein the control section is configured to stop providing the power supply voltage to the plurality of sense amplifiers of any one of the plurality of pages if the specific operation is performed on the other pages of the plurality of pages during a period of time when the specific operation is performed on the any one of the plurality of pages.

4. The semiconductor memory device as claimed in claim 1, wherein the control section is configured to not perform the specific operation on the other pages of the plurality of pages until the specific operation performed on the any one of the plurality of pages is completed if the specific operation is started on the other pages during the period of time when the specific operation is being performed on the any one of the plurality of pages.

5. The semiconductor memory device as claimed in claim 1, wherein the specific operation comprises at least one of the offset cancellation operation, a pre-sensing operation, and a bit line charging operation of the plurality of sense amplifiers.

6. The semiconductor memory device as claimed in claim 5, wherein the sequence of offset cancellation operations comprises:
the offset cancellation operation;
a charge sharing operation of the plurality of sense amplifiers, following the offset cancellation operation;
the pre-sensing operation, following the charge sharing operation; and
the bit line charging operation, following the pre-sensing operation.

7. The semiconductor memory device as claimed in claim 6, wherein the control section is configured to provide other voltages to the plurality of sense amplifiers of the any one of the plurality of pages in place of the power supply voltage when the charge sharing operation is performed on the any one of the plurality of pages.

8. The semiconductor memory device as claimed in claim 7, wherein the other voltages are lower than the power supply voltage.

9. The semiconductor memory device as claimed in claim 6, wherein the control section is configured to perform the offset cancellation operation on a (i+1)-th page after N pages are set and the offset cancellation operation performed on a i-th page is completed, wherein N is an integer greater than or equal to 2, and i is an integer greater than or equal to 1 and less than or equal to N.

10. The semiconductor memory device as claimed in claim 6, wherein the control section is configured to perform the bit line charging operation on the plurality of pages right after the pre-sensing operation performed on the plurality of pages is completed.

11. The semiconductor memory device as claimed in claim 1, wherein each of the plurality of sense amplifiers comprises:
a pair of first transistors; and
a pair of second transistors.

12. The semiconductor memory device as claimed in claim 11, wherein one of the pair of first transistors and the pair of second transistors is a pair of N-channel type field effect transistors, and another of the pair of first transistors and the pair of second transistors is a pair of P-channel type field effect transistors.

13. A control method of the semiconductor memory device, wherein the semiconductor memory device comprises a plurality of pages, a plurality of sense amplifiers and a control section, wherein each of the plurality of pages comprises a plurality of memory cells connected to the same word line, the plurality of sense amplifiers are connected to each of the plurality of memory cells, the control section performs at least one specific operation of a sequence of offset cancellation operations on the plurality of sense amplifiers of the each of the plurality of pages, the specific operation serves to provide a power supply voltage to the plurality of sense amplifiers, the power supply voltage is common to the each of the plurality of pages, and the control method comprises:
controlling, by the control section, a timing point of performing the sequence of offset cancellation operations on the each of the plurality of pages while the sequence of offset cancellation operations is being performed on the each of the plurality of pages, wherein the control method is executed as follows:
not performing the specific operation on other pages other than the any one of the plurality of pages during a period of time when the specific operation is performed on any one of the plurality of pages.
